(19) United States
(12) Patent Application Publication
(10) Pub. No.: US 2008/0296670 A1
(43) Pub. Date: Dec. 4, 2008

(54) Semiconductor Devices Including Transistors Having a Recessed Channel Region and Methods of Fabricating the Same

(75) Inventors: Ja-Young Lee, Gyeonggi (KR); Jin-Woo Lee, Gyeonggi-do (KR); Sung-Hee Han, Gyeonggi-do (KR); Tai-Su Park, Gyeonggi-do (KR); Hyun-Sook Byun, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/128,190

(22) Filed: May 28, 2008

(30) Foreign Application Priority Data
May 29, 2007 (KR) 2007-0052073

(51) Int. Cl. H01L 49/00; H01L 21/26

(52) U.S. Cl. 257/330; 438/513; 257/E21.328; 257/E49.001

(57) ABSTRACT

Some embodiments of the present invention provide semiconductor devices including a gate trench in an active region of a semiconductor substrate and a gate electrode in the gate trench. A low-concentration impurity region is provided in the active region adjacent to a sidewall of the gate trench. A high-concentration impurity region is provided between the low-concentration impurity region and the sidewall of the gate trench and along the sidewall of the gate trench. Related methods of fabricating semiconductor devices are also provided herein.

### REFERENCE TO PRIORITY APPLICATION

This application claims priority from Korean Patent Application No. 2007-0052073, filed May 29, 2007, the disclosure of which is hereby incorporated herein by reference.

### FIELD OF THE INVENTION

The present invention relates generally to semiconductor devices, and more particularly, to transistors having a recessed channel region and methods of fabricating the same.

### BACKGROUND OF INVENTION

Semiconductor devices generally use discrete devices, such as field effect transistors (FETs), as switching devices. In general, an on-current formed in a channel between source and drain regions determines the operation speed of a transistor. Typically, a gate electrode and source and drain regions are formed in a device formation region of a substrate, i.e., an active region, thereby forming a planar-type transistor. The conventional planar-type transistor has a planar channel between the source and drain regions. The on-current of such a planar-type transistor is in proportion to the width of the active region, and is in inverse proportion to the distance between the source and drain regions, i.e., the length of a gate. Therefore, the length of a gate is typically reduced to enhance the operation speed of a device by increasing the on-current. However, as an interval between the source and drain regions becomes shorter, a short channel effect may occur in the planar-type transistor. Since the conventional planar-type transistor having a channel formed in parallel on a surface of the active region is a planar-type channel device, it may be difficult to reduce the size of the device and reduce the likelihood of the occurrence of the short channel effect.

Transistors having recessed channel regions have been introduced as a plan for solving the short channel effect and reducing the size of the transistor. The recess channel transistor can increase the likelihood of an effective channel length relatively greater than the planar-type transistor. In other words, the recess channel transistor may provide a structure capable of improving problems caused by the short channel effect.

Referring to FIG. 1, a cross-section of a conventional metal oxide semiconductor (MOS) transistor having a recessed channel region will be discussed. As illustrated in FIG. 1, an isolation layer 14 defining an active region 12 is formed in a semiconductor substrate 10. A gate trench 16 is formed in the active region 12. The gate trench 16 may include upper and lower gate trenches 19 and 18, respectively. The upper gate trench 19 may intersect the active region 12, and the lower gate trench 18 may have a greater width than the upper gate trench 19. Source and drain regions 20s and 20d are formed in the active region 12 at both sides of the gate trench 16. The source and drain regions 20s and 20d may include impurities having a different conductivity type from that of the active region 12. For example, the source and drain regions 20s and 20d may be doped with n-type impurities, and the active region 12 may be doped with p-type impurities. A gate electrode 24 is provided in the gate trench 16, between the source and drain regions 20s and 20d.

When the MOS transistor is off, a voltage Vg applied to the gate electrode 24 may be a voltage less than a threshold voltage. For example, a zero or negative voltage may be applied to the gate electrode 24. At this time, a voltage Vd applied to the drain region 20d may be a positive voltage. Voltages Vs and Vb respectively applied to the source region 20s and the semiconductor substrate 10 may be ground voltages.

Meanwhile, when the MOS transistor is in an off state, a depletion region may be produced between the gate electrode 24 and the drain region 20d. A gate-induced drain leakage (GIDL) current IL may be generated due to the depletion region. In portions overlapping with the gate electrode 24, the drain region 20d adjacent to an upper edge of the upper gate trench 19 has a corner having a right angle to the upper edge of the upper gate trench 19. As a result, an electric field clouding effect may occur at an upper corner of the drain region 20d. Therefore, the GIDL current I_{L} may be more increased due to the electric field clouding effect. Consequently, the GIDL current results in degrading an off characteristic of the MOS transistor having the recessed channel region.

A semiconductor device including a MOS transistor having a recessed channel region is discussed in U.S. Pat. No. 6,476,444, entitled Semiconductor device and method of fabricating the same to Min, the disclosure of which is hereby incorporated herein by reference as if set forth in its entirety.

### SUMMARY OF THE INVENTION

Some embodiments of the present invention provide semiconductor devices capable of reducing a leakage current in an off state of a transistor and methods of fabricating the same. The semiconductor device includes a gate trench formed in an active region of a semiconductor substrate. A gate electrode filling the gate trench is provided. A low-concentration impurity region is formed in the active region adjacent to a sidewall of the gate trench. A high-concentration impurity region is interposed between the low-concentration impurity region and the sidewall of the gate trench and formed along the sidewall of the gate trench.

In further embodiments of the present invention, the high-concentration impurity region may have a higher level than a bottom of the low-concentration impurity region.

In still further embodiments of the present invention, the high-concentration impurity region may have an impurity concentration gradually reduced downward from a surface of the semiconductor substrate.

In some embodiments of the present invention, the high-concentration and low-concentration regions may have bottoms positioned at higher levels than a bottom region of the gate trench.

In further embodiments of the present invention, the gate trench may include an upper gate trench formed in the active region. A lower gate trench formed beneath the upper gate trench may have a greater width than the upper gate trench and a spherical shape. In certain embodiments, the gate electrode may be buried in the gate trench.

In still further embodiments of the present invention, the semiconductor device may further include a contact plug positioned on the high-concentration and low-concentration impurity regions. The contact plug may be a doped poly-silicon layer.

Some embodiments of the present invention provide methods of fabricating a semiconductor device including forming a preliminary impurity region in an active region of a semiconductor substrate. A first gate trench passing through the preliminary impurity region is formed. A high-concentration impurity region is formed in the preliminary impurity region adjacent to a sidewall of the first gate trench. The high-concentration impurity region is formed along the sidewall of the first gate trench. A second gate trench is formed beneath the first gate trench. A low-concentration impurity region is formed in the preliminary impurity region adjacent to the high-concentration impurity region.

In further embodiments of the present invention, the high-concentration impurity region may be formed by selectively implanting impurity ions into the preliminary impurity region through an inner wall surface of the first gate trench. At this time, the impurity ion implantation may be performed using a plasma doping technique or tilt ion implantation technique.

In still further embodiments of the present invention, the forming of the first gate trench may include sequentially forming a first upper gate trench and a first lower gate trench in the active region. Before forming the first lower gate trench, a preliminary high-concentration impurity region may be formed in the preliminary impurity region adjacent to a sidewall of the first upper gate trench.

In some embodiments of the present invention, the low-concentration impurity region may be formed while forming the high-concentration impurity region or the second gate trench.

In further embodiments of the present invention, the forming of the first gate trench may include forming a mask pattern for exposing a predetermined region of the preliminary impurity region. A sacrificial spacer may be formed on a sidewall of the mask pattern. The preliminary impurity region exposed by the sacrificial spacer may be etched using the mask pattern and the sacrificial spacer as etching masks. Before forming the sacrificial spacer, impurity ions may be implanted into the exposed preliminary impurity region such that the preliminary impurity region exposed by the mask pattern has an impurity concentration gradually reduced downward from a surface of the semiconductor substrate.

Still further embodiments of the present invention provide methods of fabricating a semiconductor device including forming a first gate trench in an active region of a semiconductor substrate. A high-concentration impurity region is formed in the active region adjacent to a sidewall of the first gate trench. At this time, the high-concentration impurity region is formed along the sidewall of the first gate trench. A second gate trench is formed beneath the first gate trench. A gate electrode filling the first and second gate trenches is formed. Impurity ions are implanted into the active region using the gate electrode as an ion implantation mask, thereby forming a low-concentration impurity region adjacent to the high-concentration impurity region.

### BRIEF DESCRIPTION OF THE DRAWINGS

FIG. 1 is a cross-section illustrating a conventional MOS transistor having a recessed channel region.

FIG. 2 is a cross section illustrating semiconductor devices according to some embodiments of the present invention.

FIG. 3 is a cross section illustrating semiconductor devices according to some embodiments of the present invention.

FIG. 4 is a cross section illustrating semiconductor devices according to some embodiments of the present invention.

FIGS. 5A through 5E are cross sections illustrating processing steps in the fabrication of semiconductor devices according to some embodiments of the present invention.

FIGS. 6A and 6B are cross sections illustrating processing steps in the fabrication of semiconductor devices according to some embodiments of the present invention.

FIGS. 7A and 7B are cross sections illustrating processing steps in the fabrication of semiconductor devices according to some embodiments of the present invention.

FIGS. 8A through 8C are cross sections illustrating are cross sections illustrating processing steps in the fabrication of semiconductor devices according to some embodiments of the present invention.

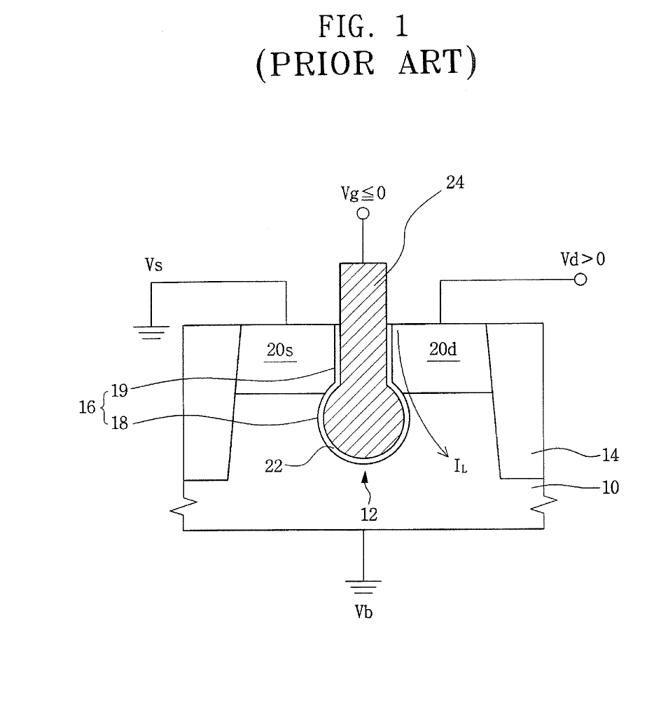

### DETAILED DESCRIPTION OF THE INVENTION

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

Example embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

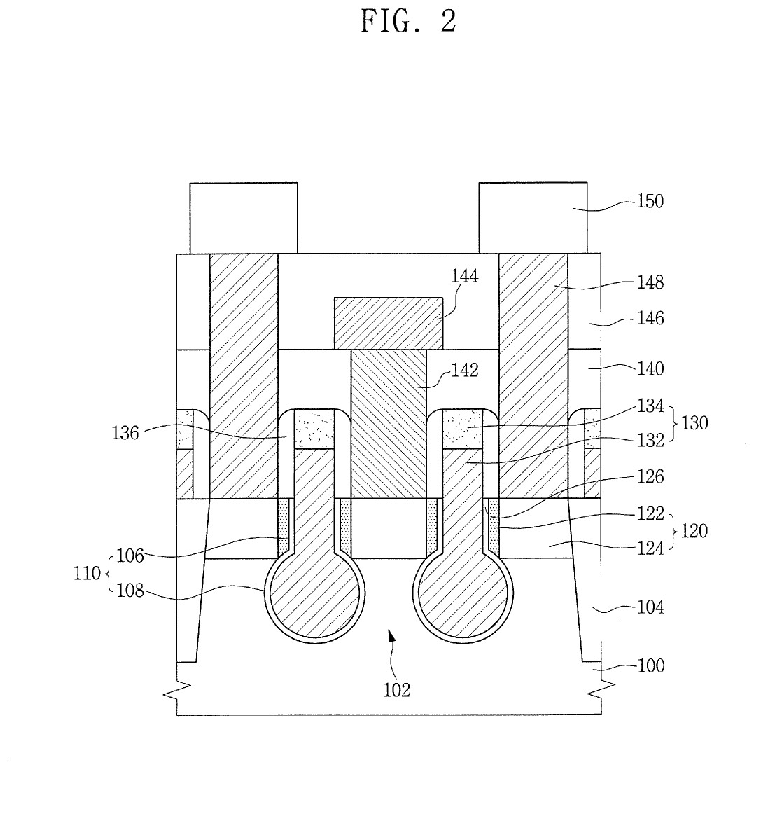

Referring first to FIG. 2, semiconductor devices according to some embodiments of the present invention will be discussed. As illustrated in FIG. 2, isolation layer 104 defining an active region 102 may be formed in a semiconductor substrate 100. The active region 102 may include, for example, a single crystalline silicon layer. The active region 102 may be doped with p-type impurities. Gate trenches 110 are arranged in the active region 102. The gate trenches 110 include first and second gate trenches 106 and 108. The first and second gate trenches 106 and 108 may be respectively upper and lower gate trenches. Specifically, the first gate trenches 106 may intersect the active region 102, and the second gate trenches 108 may have greater widths than the first gate trenches 106. The second gate trenches 108 may have rounded sidewalls and bottom regions. In other words, in some embodiments of the present invention, the second gate trenches 108 may have spherical shapes.

Impurity regions 120 may be formed in the active region 102 at both sides of the gate trenches 110. The impurity regions 120 may have higher levels than the bottom regions of the gate trenches 110, such that a channel region is formed between the impurity regions 120. The impurity regions 120 include high-concentration impurity regions 122 formed along sidewalls of the gate trenches 110 and low-concentration impurity regions 124 formed in the active region 102 adjacent to the high-concentration impurity regions 122. The high-concentration and low-concentration impurity regions 122 and 124 may be doped with impurities having a conductivity type different from that of the active region 102. For example, the impurity may include phosphorus (P) as an n-type impurity. The high-concentration impurity regions 122 may have junction depths substantially equal to or deeper than the first gate trenches 106. Furthermore, the low-concentration impurity regions 124 may have junction depths substantially equal to the high-concentration impurity regions 122. That is, the high-concentration impurity regions 122 may be interposed between the low-concentration impurity regions 124 and the sidewalls of the gate trenches 110. Meanwhile, the impurity regions 120 may be divided into a source region in the active region 102 at one side of the gate trench 110 and a drain region in the active region 102 at the other side of the gate trench 110. For example, in FIG. 2, the drain region may be positioned in the active region 102 between the gate trenches 110 and the isolation layer 104. Furthermore, the source region may be positioned in the active region 102 between the gate trenches 110.

Gate patterns 130 may be formed in the gate trenches 110. The gate patterns 130 may include gate electrodes 132 and insulating patterns 134 positioned on the gate electrodes 132, which are sequentially stacked. The gate electrodes 132 may be provided in the gate trenches 110 and may have projections positioned at higher levels than the impurity regions 120. The gate electrode 132 may include a conductive layer such as an n-type doped poly-silicon layer, a metal layer, a metal silicide layer or a combination layer thereof. In addition, gate spacers 136 may be formed on the sidewalls of the gate electrodes 132 and the insulating patterns 134 protruded from the impurity regions 120.

Gate dielectric layers 126 may be interposed between the gate electrodes 132 and the gate trenches 110. The gate dielectric layers 126 may include thermal oxide layers or high-k dielectric layers.

Thus, according to some embodiments of the present invention, a MOS transistor having a recessed channel region may be provided in the active region 102. In some embodiments of the present invention, when the MOS transistor is in an off state, a depletion region may be produced in the drain region overlapping with the first gate trench 106. In these embodiments, the high-concentration impurity region 122 may function to suppress the production of the depletion region in the drain region. Moreover, the production of the depletion region is suppressed in an electric field concentration region such as an upper corner of the drain region, and a gate-induced drain leakage (GIDL) current may be reduced.

A lower insulating layer 140 may cover the entire surface of the semiconductor substrate 100 having the gate patterns 130. The lower insulating layer 140 may include a silicon nitride (SiN) layer, a silicon oxide (SiO₂) layer, a silicon oxynitride (SiON) layer, a low-k dielectric layer or any combination layer thereof. The lower insulating layer 140 may have a planarized upper surface.

A bit line 144 may be positioned on the lower insulating layer 140. The bit line 144 may be electrically connected to any one selected from the impurity regions 120 through a first contact plug passing through the lower insulating layer 140, for example, a bit line plug 142. That is, one end of the bit line plug 142 may come into contact with the bit line 144, and the other end of the bit line plug 142 may come into contact with the source region in the impurity regions 120. The bit line plug 142 may include an n-type doped poly-silicon layer. The bit line 144 may include a conductive layer such as a poly-silicon layer, a metal layer, a metal silicide layer or a combination layer thereof.

The bit line 144 and the lower insulating layer 140 may be covered by an upper insulating layer 146. The upper insulating layer 146 may include a SiN layer, a SiO₂ layer, a SiON layer, a low-k dielectric layer or a mixture layer thereof. The upper insulating layer 146 may have a planarized upper surface.

Data storage elements 150 may be positioned on the upper insulating layer 146. The data storage elements 150 may be capacitors constituting a DRAM cell. The data storage element 150 may include a lower electrode, a capacitor dielectric layer and an upper electrode, which are sequentially stacked. In this case, a data retention characteristic of a semiconductor device such as DRAM can be enhanced due to the reduction of the GIDL current as described above. The data storage element 150 may be electrically connected to another one selected from the impurity regions 120 through a second contact plug sequentially passing through the upper and lower insulating layers 146 and 140, e.g., a storage plug 148. That is, one end of the storage plug 148 may come into contact with the data storage element 150, and the other end of the storage plug 148 may come into contact with the drain region. The storage plug 148 may include an n-type doped poly-silicon layer.

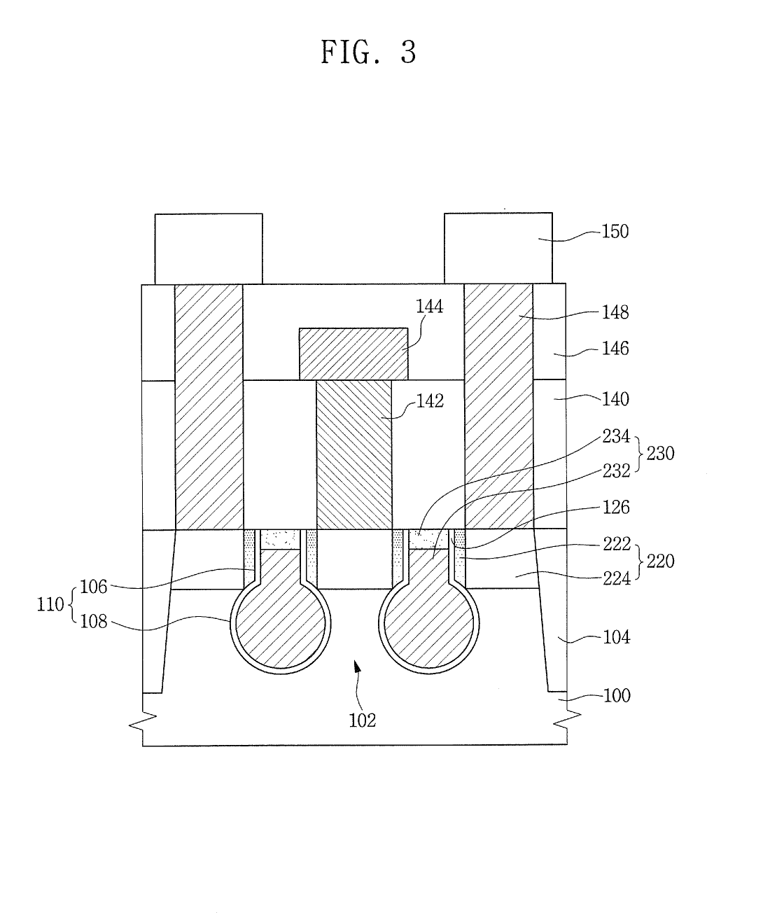

Referring now to FIG. 3, a cross section of semiconductor devices according to some embodiments of the present invention will be discussed. Like reference numerals refer to like elements throughout. As illustrated in FIG. 3, isolation layer 104 defining an active region 102 is formed in a semiconductor substrate 100 as described with reference to FIG. 2. The active region 102 may be doped with p-type impurities. Gate trenches 110 are arranged in the active region 102. As discussed with respect to FIG. 2, the gate trenches 110 may include first gate trenches 106 intersecting the active region 102, and second gate trenches 108 formed beneath the first gate trenches 106 and having greater widths that the first gate trenches 106.

Impurity regions 220 may be formed in the active region 102 at both sides of the gate trenches 110. The impurity regions 220 include high-concentration impurity regions 222 formed along the sidewalls of the gate trenches 110, and low-concentration impurity regions 224 formed in the active region 102 adjacent to the high-concentration impurity regions 222. That is, the high-concentration impurity regions 222 are interposed between the low-concentration impurity regions 224 and the sidewalls of the gate trenches 110. The high-concentration and low-concentration impurity regions 222 and 224 may be doped with n-type impurities, and the impurity may include phosphorus (P) as an n-type impurity. In some embodiments of the present invention, the high-concentration impurity regions 222 may have an impurity concentration, which is gradually decreased downward from the surface of the semiconductor substrate 100. Since the junction depths of the high-concentration and low-concentration impurity regions 222 and 224 and the level of the impurity regions 120 are substantially similar to those discussed above with respect to FIG. 2, detailed descriptions thereof will therefore be omitted in the interest of brevity.

Gate patterns 230 may be formed in the gate trenches 110. The gate patterns 230 may include gate electrodes 232 and insulating patterns 234 positioned on the gate electrodes 232, which are sequentially stacked. The gate electrodes 232 may be buried in the gate trenches 110. Gate dielectric layers 126 may be interposed between the gate electrodes 232 and the gate trenches 110.

Thus, according to some embodiments of the present invention, a MOS transistor having a recessed channel may be provided. In these embodiments, since the high-concentration impurity regions 222 have high concentration impurities in regions adjacent to edges of the gate electrodes 132, the GIDL current may be reduced as described above. Moreover, since the high-concentration impurity regions 222 have low concentration impurities in regions adjacent to a channel region along the second gate trenches 108 between the impurity regions 220, the degradation of a leakage characteristic generated in a channel can be prevented.

A lower insulating layer 140 may be formed on the semiconductor substrate 100 having the gate pattern 230. A bit line 144 may be positioned on the lower insulating layer 140. The bit line 144 may be electrically connected to any one selected from the impurity regions 120 through a first contact plug passing through the lower insulating layer 140, e.g., a bit line plug 142. An upper insulating layer 146 may be formed on the bit line 144 and the lower insulating layer 140. Data storage elements 150 may be positioned on the upper insulating layer 146. The data storage elements 150 may be capacitors constituting a DRAM cell. The data storage element 150 may be electrically connected to another one selected from the impurity regions 120 through a second contact plug sequentially passing through the upper and lower insulating layers 146 and 140, e.g., a storage plug 148. Since the bit line 144, the bit line plug 142, the data storage element 150 and the storage plug 148 are substantially similar to those discussed above with respect to FIG. 2; detailed descriptions thereof will therefore be omitted in the interest of brevity.

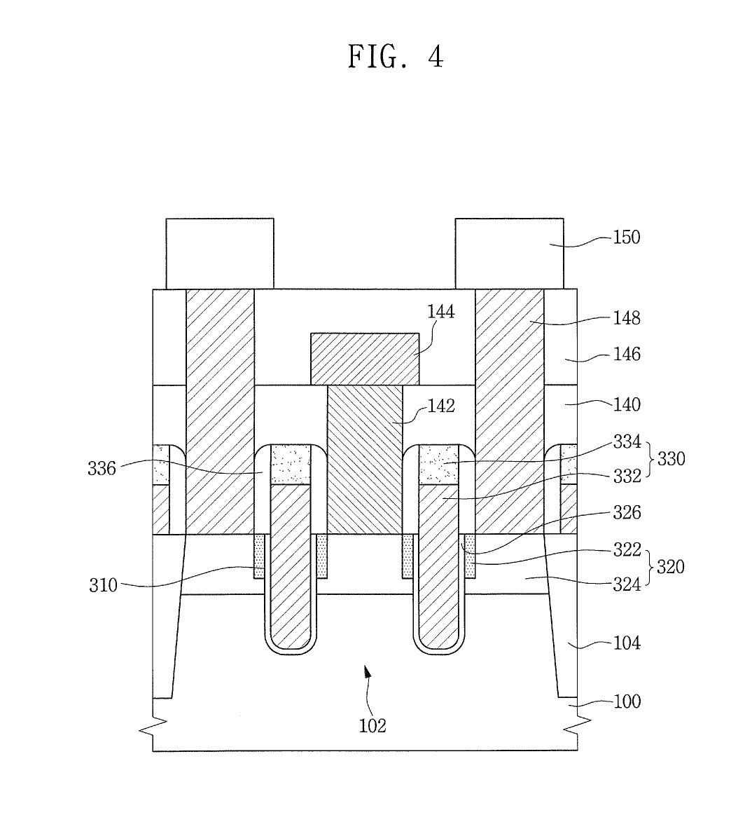

Referring now to FIG. 4, a cross section of semiconductor devices according to some embodiments of the present invention will be discussed. As illustrated in FIG. 4, isolation layer 104 defining an active region 102 may be formed on a semiconductor substrate 100 as discussed above with respect to FIG. 2. The active region 102 may be doped with p-type impurities. Gate trenches 310 are arranged in the active region 102. The gate trenches 310 may intersect the active region 102 and may have vertical sidewalls and rounding edges at bottoms of the gate trenches 310.

Impurity regions 320 may be formed in the active region 102 at both sides of the gate trenches 310. The impurity regions 320 include high-concentration impurity regions 322 formed along the sidewalls of the gate trenches 110, and low-concentration impurity regions 324 formed in the active region 102 adjacent to the high-concentration impurity regions 322. The high-concentration and low-concentration impurity regions 322 and 324 may be doped with n-type impurities, and the impurity may include P as an n-type impurity. In some embodiments of the present invention, the high-concentration impurity regions 322 may have higher levels than bottoms of the low-concentration impurity regions 324. In other words, the high-concentration impurity regions 322 may have shallower junction depths than the low-concentration impurity regions 324.

Gate patterns 330 may be formed in the gate trenches 310. The gate patterns 330 may include gate electrodes 332 and insulating patterns 334 positioned on the gate electrodes 332, which are sequentially stacked. The gate electrodes 332 may be provided in the gate trenches 310 and may have projections positioned at higher levels than the impurity regions 320. In these embodiments, gate electrodes may be buried in the gate trenches 310. Furthermore, gate spacers 336 may be formed on sidewalls of the insulating patterns 334 and the gate electrodes 332 protruded from the impurity regions 320. Gate dielectric layers 326 may be interposed between the gate electrodes 332 and the gate trenches 310.

Thus, according to some embodiments of the present invention, a MOS transistor having a recessed channel region may be provided in the active region 102. In some embodiments of the present invention, since the high-concentration impurity regions 322 have high-concentration impurities in regions adjacent to upper edges of the gate trenches 310, the GIDL current may be reduced as discussed above. Moreover, since the high-concentration impurity regions 322 have low-concentration impurities in regions adjacent to a channel region provided along the lower portions of gate trenches 310 between the impurity regions 320, the degradation of a leakage characteristic generated in a channel can be prevented.

A lower insulating layer 140 may be formed on the semiconductor substrate 100 having the gate patterns 330. A bit line 144 may be positioned on the lower insulating layer 140. The bit line 144 may be electrically connected to any one selected from the impurity regions 320 through a first contact plug passing through the lower insulating layer 140, e.g., a bit line plug 142. An upper insulating layer 146 may be formed on the bit line 144 and the lower insulating layer 140. Data storage elements 150 may be positioned on the upper insulating layer 146. The data storage elements 150 may be capacitors constituting a DRAM cell. The data storage element 150 may be electrically connected to another one selected from the impurity regions 320 through a second contact plug sequentially passing through the upper and lower insulating layers 146 and 140, e.g., a storage plug 148. Since the bit line 144, the bit line plug 142, the data storage element 150 and the storage plug 148 are substantially similar to those discussed above with respect to FIG. 2; detailed descriptions thereof will be omitted herein in the interest of brevity.

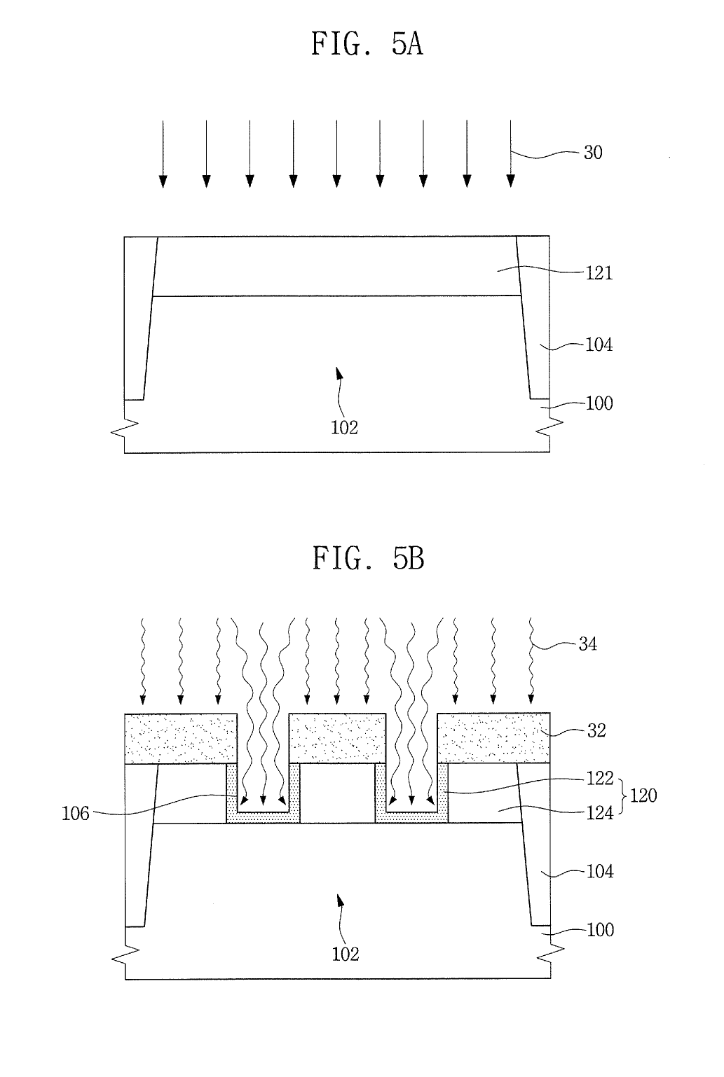

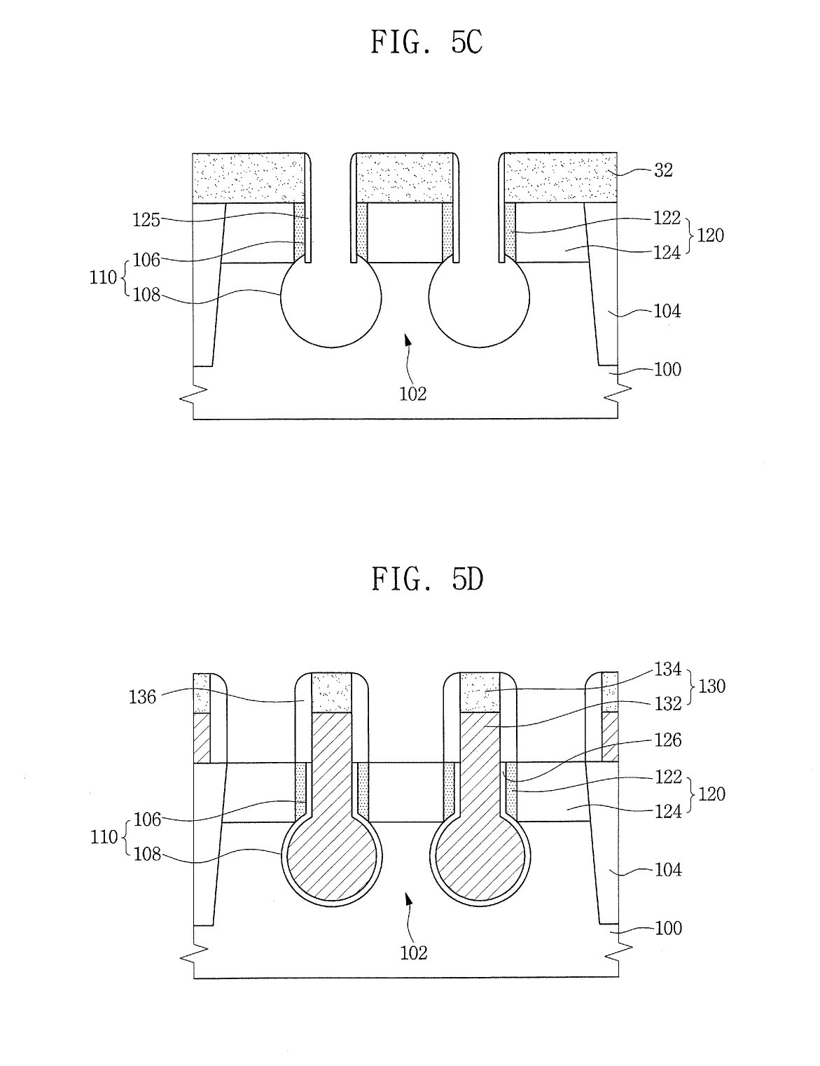

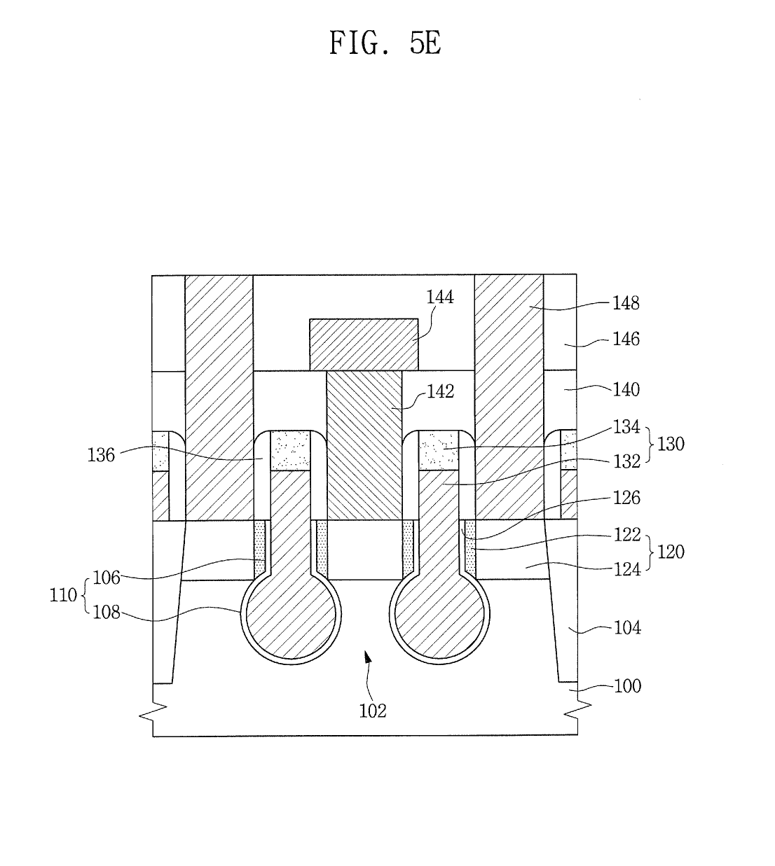

Processing steps in the fabrication of semiconductor devices according to some embodiments of the present invention will now be discussed with respect to FIGS. 2 and 5A through 5E. As illustrated in FIG. 5A, isolation layer 104 defining an active region 102 may be formed in a semiconductor substrate 100. The isolation layer 104 may include silicon oxide layers. The active region 102 may include a single crystalline silicon layer. The active region 102 may be doped with p-type impurity ions. A preliminary impurity region 121 is formed in the active region 102. The preliminary impurity region 121 may be doped with n-type impurity ions 30 different from the conductivity type of the active region 102 through an ion implantation method that is generally known.

Referring now to FIG. 5B, a mask pattern 32 for exposing a predetermined region of the preliminary impurity region 121 may be formed. For example, the mask pattern 32 may be formed to have openings intersecting the preliminary impurity region 121. The mask pattern 32 may include a silicon nitride layer. The preliminary impurity region 121 is anisotropically etched using the mask pattern 32 as an etching mask, thereby forming first gate trenches 106. The first gate trenches 106 may be formed to have levels substantially equal to or lower than the preliminary impurity region 121. In some embodiments, the first gate trenches 106 may be formed to have higher levels than the preliminary impurity region 121.

Subsequently, n-type impurity ions 34 are implanted into the preliminary impurity region 121 through exposed inner wall surfaces of the first gate trenches 106 using the mask pattern 32 as an ion implantation mask. As a result, high-concentration impurity regions 122 are formed in the preliminary impurity region 121 along sidewalls of the first gate trenches 106. Specifically, the high-concentration impurity regions 122 may be formed to have levels substantially equal to the preliminary impurity region 121. Impurity ions including a phosphorous may be implanted into the high-concentration impurity regions 122 through a plasma doping technique or tilt ion implantation technique (not shown), in which three-dimensional ion implantation is possible.

Meanwhile, when the first gate trenches 106 have levels substantially equal to or lower than the preliminary impurity region 121, the preliminary impurity region 121 adjacent to the high-concentration impurity regions 122 may be changed into low-concentration impurity regions 124 in the process of forming the high-concentration impurity regions 122. That is, the high-concentration impurity regions 122 may be interposed between the low-concentration impurity regions 124 and the sidewalls of the first gate trenches 106. As a result, impurity regions 120 including the high-concentration and low-concentration impurity regions 122 and 124 may be formed.

Referring now to FIG. 5C, spacers 125 may be formed on the sidewalls of the first gate trenches 106 and the mask pattern 32. The spacers 125 may include, for example, silicon oxide layers. The active region 102 beneath the first gate trenches 106 may be isotropically etched using the mask pattern 32 and the spacers 125 as etching masks, thereby forming second gate trenches 108 having greater widths than the first gate trenches 106. Thus, gate trenches 110 including the first and second gate trenches 106 and 108 may be formed. The second gate trenches 108 may be formed to have rounded sidewalls and rounded bottom regions. Meanwhile, when the first gate trenches 106 have higher levels that the preliminary impurity region 121, the preliminary impurity region 121 adjacent to the high-concentration impurity regions 122 may be changed into the low-concentration impurity regions 124 in the process of forming the second gate trenches 108.

Referring now to FIG. 5D, after removing the mask pattern (32 of FIG. 5C) and the spacers (125 of FIG. 5C), gate dielectric layers 126 may be formed on the semiconductor substrate 100 having the gate trenches 110. The gate dielectric layers 126 may include thermal oxide layers or high-k dielectric layers.

Subsequently, gate patterns 130 are formed on the gate dielectric layers 126. The gate patterns 130 may fill the gate trenches 110. Furthermore, the gate patterns 130 may be formed to fill the gate trenches 110 and to have projections positioned at higher levels than the impurity regions 120. More specifically, a conductive layer and a capping layer may be sequentially stacked on the semiconductor substrate 100 having the gate dielectric layers 126, and the sequentially-stacked conductive layer and capping layer may be patterned. As a result, the gate patterns 130 including the sequentially-stacked gate electrodes 132 and insulating patterns 134 may be formed. At this time, the gate electrodes 132 may fill the gate trenches 110. The gate electrode 132 may include a conductive layer such as an n-type doped poly-silicon layer, a metal layer, a metal silicide layer or a combination layer thereof. After that, gate spacers 136 may be formed on the sidewalls of the insulating patterns 134 and the gate electrodes 132 positioned at higher levels than the impurity regions 120.

Referring now to FIG. 5E, a lower insulating layer 140 may be formed to cover the entire surface of the semiconductor substrate 100 having the gate patterns 130. The lower insulating layer 140 may include a silicon nitride layer, a silicon oxide layer, a silicon oxynitride layer, a low-k dielectric layer, or a mixture layer thereof. The lower insulating layer 140 is planarized, thereby forming a flat upper surface.

Subsequently, a first contact plug passing through the lower insulating layer 140, for example, a bit line plug 142, may be formed. The bit line plug 142 may be formed to come into contact with any one selected from the impurity regions 120, for example, a source region. The bit line plug 142 may include an n-type doped poly-silicon layer. After that, a bit line 144 may be formed on the bit line plug 142. The bit line 144 may include a conductive layer such as a poly-silicon layer, a metal layer, a metal silicide layer or any combination layer thereof.

Subsequently, an upper insulating layer 146 may be formed to cover the lower insulating layer 140 and the bit line 144. The upper insulating layer 146 may include a SiN layer, a SiO₂ layer, a SiON layer, a low-k dielectric layer or any combination layer thereof. The upper insulating layer 146 is planarized, thereby forming a flat upper surface.

Second contact plugs, for example, storage plugs 148 may be formed to come into contact with drain regions that are ones selected from the impurity regions 120 by passing through the upper and lower insulating layers 146 and 140. The storage plugs 148 may include n-type doped poly-silicon layers. In the aforementioned process of forming the bit line plug 142 and the storage plugs 148, n-type impurity ions contained in the plugs 142 and 148 may be diffused into the impurity regions 120. However, the plugs 142 and 148 may be formed without change of the concentrations of the high-concentration and low-concentration impurity regions 122 and 124.

Referring again to FIG. 2, a data storage element 150 may be formed on the storage plug 148. The data storage element 150 may be a capacitor constituting a DRAM cell. In these embodiments, the data storage element 150 may include a lower electrode, a capacitor dielectric layer and an upper electrode, which are sequentially stacked.

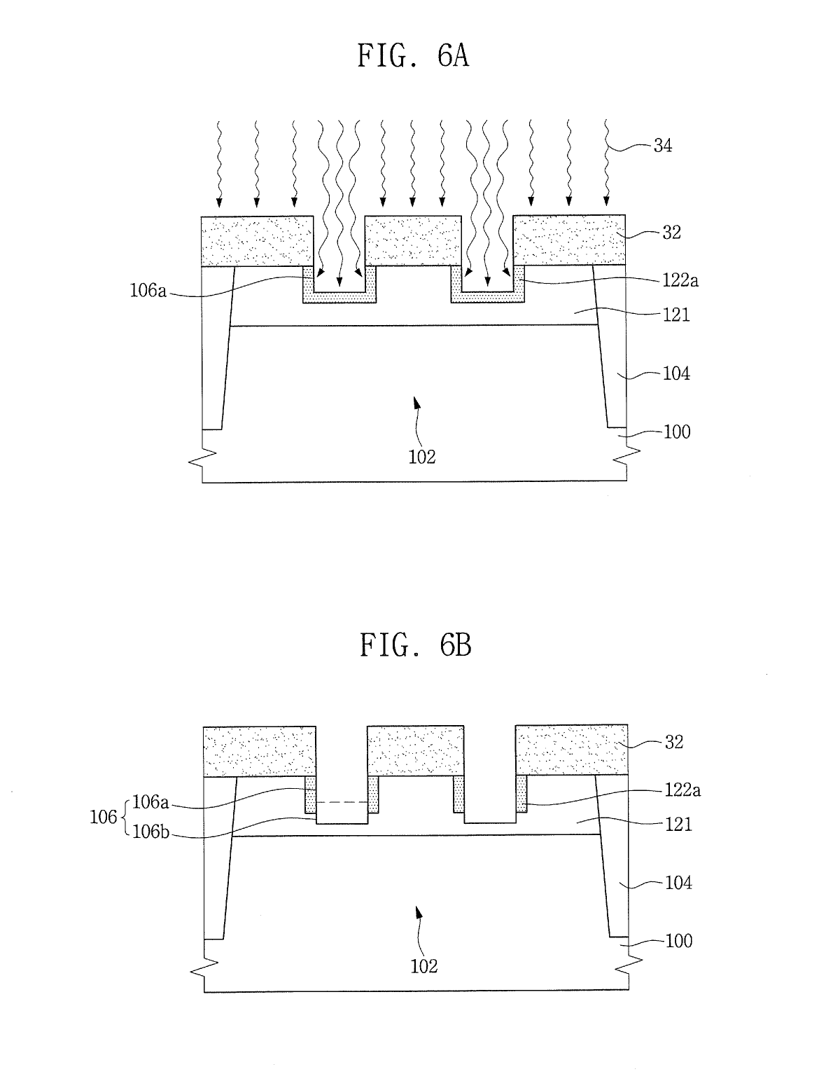

Referring now to FIGS. 6A and 6B, cross sections illustrating processing steps in the fabrication of semiconductor devices according to some embodiments of the present invention will be discussed. The method illustrated in FIGS. 6A and 6B is similar to the method discussed above with respect to FIGS. 5A through 5E, except that the methods of forming high-concentration impurity regions is different. Accordingly, only the processing steps in the formation of a high-concentration impurity region will be discussed with respect to FIGS. 6A and 6B.

Referring to FIG. 6A, after forming a preliminary impurity region 121 doped with n-type impurities in an active region 102, a mask pattern 32 for exposing a predetermined region of the preliminary impurity region 121 may be formed. The mask pattern 32 may be formed to have openings intersecting the preliminary impurity region 121. After that, the preliminary impurity region 121 is anisotropically etched using the mask pattern 32 as an etching mask, thereby forming first upper gate trenches 106a.

Subsequently, n-type impurity ions 34 are implanted into the preliminary impurity region 121 through exposed inner wall surfaces of the first upper gate trenches 106a using the mask pattern 32 as an ion implantation mask. As a result, preliminary high-concentration impurity regions 122a are formed in the preliminary impurity region 121 along sidewalls of the first upper gate trenches 106a. Impurity ions including P may be implanted into the preliminary high-concentration impurity regions 122a through a plasma doping technique in which three-dimensional ion implantation is possible or tilt ion implantation technique (not shown).

Referring to FIG. 6B, the exposed preliminary impurity region 121 is anisotropically etched using the mask pattern 32 as an etching mask, thereby forming first lower gate trenches 106b. As a result, first gate trenches 106 including the first upper gate trenches 106a and the first lower gate trenches 106b may be formed.

In a subsequent process, a heat treatment process is performed with respect to the preliminary high-concentration impurity regions 122a, so that the n-type impurity ions can be diffused into a portion adjacent to the first upper gate trench 106a. As a result, the high-concentration impurity regions (See 122 of FIG. 2) may be formed along the first gate trenches (See 106 of FIG. 2).

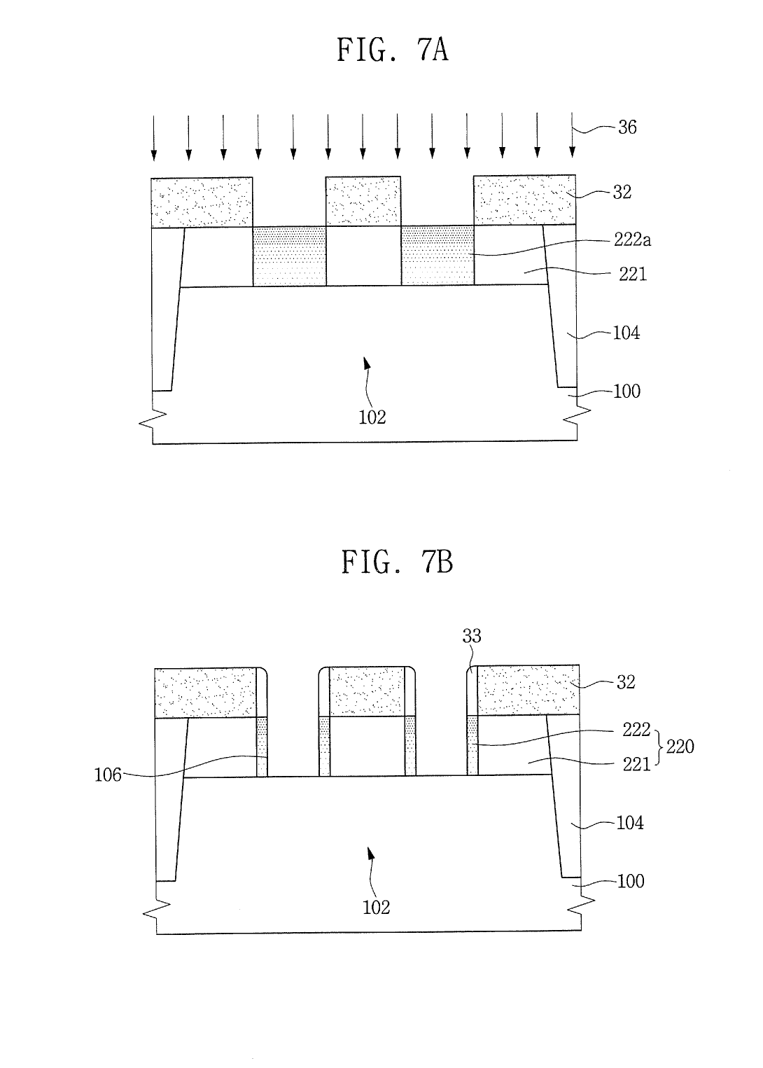

Referring now to FIGS. 7A and 7B, cross sections illustrating processing steps in the fabrication of semiconductor devices according to some embodiments of the present invention will be discussed. The method illustrated in FIGS. 7A and 7B is similar to the method discussed above with respect to FIGS. 5A through 5E, except that the methods of forming high-concentration impurity regions is different. Accordingly, only the processing steps in the formation of a high-concentration impurity region will be discussed with respect to FIGS. 7A and 7B.

As illustrated in FIG. 7A, after forming a preliminary impurity region 221 doped with n-type impurities in an active region 102, a mask pattern 32 for exposing a predetermined region of the preliminary impurity region 221 may be formed. The mask pattern 32 may be formed to have openings intersecting the preliminary impurity region 221.

Subsequently, n-type impurity ions 36 may be implanted into the preliminary impurity region 221 using the mask pattern 32 as an ion implantation mask so as to have an impurity concentration gradually reduced downward from the surface of the exposed preliminary impurity region 221. As a result, the exposed preliminary impurity region 221 may be changed into a preliminary high-concentration impurity region 222a having a concentration gradient gradually reduced downward from the surface of the preliminary high-concentration impurity region 222a.

Referring to FIG. 7B, sacrificial spacers 33 may be formed on the sidewalls of the mask pattern 32. The preliminary high-concentration impurity region 222a exposed by the sacrificial spacers 33 is anisotropically etched using the mask pattern 32 and the sacrificial spacers 33 as etching masks, thereby forming first gate trenches 106. Moreover, the preliminary high-concentration impurity regions 222a having a gradient at lower portions of the sacrificial spacers 33 may be changed into high-concentration impurity regions 222 having a gradient.

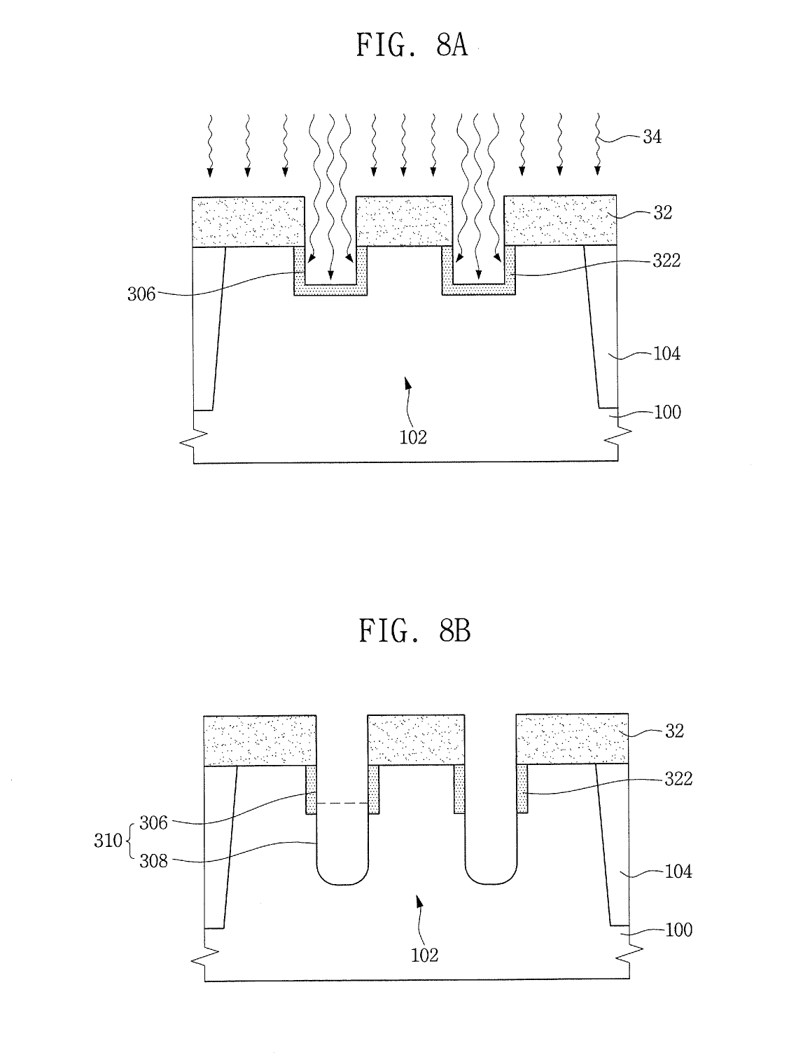

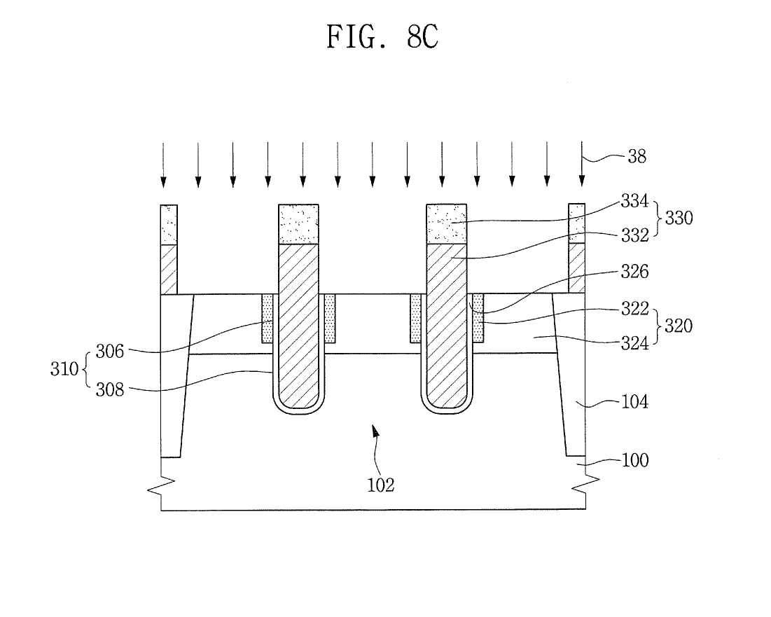

FIGS. 8A through 8C are cross sections illustrating processing steps in the fabrication of semiconductor devices according to some embodiments of the present invention. The method illustrated in FIGS. 8A through 8C is similar to the method discussed above with respect to FIGS. 5A through 5E, except that the methods of forming high-concentration and low-concentration impurity regions are different. Accordingly, only the processing steps in the formation of the high-concentration and low-concentration impurity regions will be discussed with respect to FIGS. 8A through 8C.

Referring first to FIG. 8A, a process of forming a preliminary impurity region 121 discussed above with respect to FIG. 5A will be omitted. A mask pattern 32 for exposing a predetermined region of an active region 102 doped with p-type impurities may be formed. The mask pattern 32 may be formed to have openings intersecting the active region 102. After that, the active region 102 is anisotropically etched using the mask pattern 32 as an etching mask, thereby forming first gate trenches 306.

Subsequently, n-type impurity ions 34 are implanted into the active region 102 through the exposed inner wall surfaces of the first gate trenches 306 using the mask pattern 32 as an ion implantation mask. As a result, high-concentration impurity regions 322 may be formed in the active region 102 along the sidewalls of the first gate trenches 306. Meanwhile, n-type impurity ions including P may be implanted into the high-concentration impurity regions 322 through a plasma doping technique in which three-dimensional ion implantation is possible or tilt ion implantation technique (not shown).

Referring now to FIG. 8B, the exposed active region 102 is anisotropically etched using the mask pattern 32 as an etching mask, thereby forming second gate trenches 308 beneath the first gate trenches 306. As a result, gate trenches 310 including the first and second gate trenches 306 and 308 may be formed. In some embodiments, the second gate trenches 308 may be formed to have widths substantially equal to the first gate trenches 306.

Referring now to FIG. 8C, after removing the mask pattern 32, gate dielectric layers 326 may be formed on the gate trenches 310. After that, gate patterns 330 filling the gate trenches 330 may be formed on the gate dielectric layers 326. The gate patterns 330 may include gate electrodes 332 and insulating patterns 334 formed on the gate electrodes 332. The gate patterns 330 may be formed to have projections positioned at higher levels than the active layer 102.

Subsequently, n-type impurity ions 38 may be implanted into the active region 102 at both sides of the gate patterns 330 using the gate patterns 330 as an ion implantation mask. As a result, low-concentration impurity regions 324 adjacent to the high-concentration impurity regions 322 may be formed. At this time, the low-concentration impurity regions 324 may be formed to have lower levels than the high-concentration impurity regions 322 by adjusting implantation energy of the n-type impurity ions 38.

As discussed above, according to some embodiments of the present invention, an impurity region including a high-concentration impurity region adjacent to an upper edge of a gate trench is provided in a MOS transistor having a recessed channel region. As a result, when the MOS transistor is in an off state, a depletion region produced in an upper corner of a drain region adjacent to the upper edge of the gate trench can be reduced. Accordingly, GIDL current may be reduced, so that a semiconductor device employing the MOS transistor can have a leakage current characteristic enhanced in the off state of the MOS transistor.

While the present invention has been particularly shown and described with reference to exemplary embodiments thereof, it will be understood by those of ordinary skill in the art that various changes in form and details may be made therein without departing from the spirit and scope of the present invention as defined by the following claims.

That which is claimed is:

1. A semiconductor device comprising:
a gate trench in an active region of a semiconductor substrate;
a gate electrode in the gate trench;
a low-concentration impurity region in the active region adjacent to a sidewall of the gate trench; and
a high-concentration impurity region between the low-concentration impurity region and the sidewall of the gate trench and along the sidewall of the gate trench.

2. The semiconductor device of claim 1, wherein the high-concentration impurity region has a higher level than a bottom of the low-concentration impurity region.

3. The semiconductor device of claim 1, wherein the high-concentration impurity region has an impurity concentration gradually reduced downward from a surface of the semiconductor substrate.

4. The semiconductor device of claim 1, wherein the high-concentration and low-concentration regions have bottoms positioned at higher levels than a bottom region of the gate trench.

5. The semiconductor device of claim 1, wherein the gate trench comprises:
an upper gate trench provided in the active region; and
a lower gate trench provided beneath the upper gate trench, the lower gate trench having a greater width than the upper gate trench and a spherical shape.

6. The semiconductor device of claim 1, wherein the gate electrode is buried in the gate trench.

7. The semiconductor device of claim 1, further comprising a contact plug on the high-concentration and low-concentration impurity regions, wherein the contact plug is a doped poly-silicon layer.

8. A method of fabricating a semiconductor device, comprising:
forming a preliminary impurity region in an active region of a semiconductor substrate;
forming a first gate trench through the preliminary impurity region;
forming a high-concentration impurity region in the preliminary impurity region adjacent to a sidewall of the first gate trench, the high-concentration impurity region being formed along the sidewall of the first gate trench;
forming a second gate trench beneath the first gate trench; and
forming a low-concentration impurity region in the preliminary impurity region adjacent to the high-concentration impurity region.

9. The method of claim 8, wherein the low-concentration impurity region is formed to have a lower level than a bottom of the high-concentration impurity region.

10. The method of claim 8, wherein the high-concentration impurity region is formed by selectively implanting impurity ions into the preliminary impurity region through an inner wall surface of the first gate trench.

11. The method of claim 10, wherein the impurity ion implantation is performed using a plasma doping technique or tilt ion implantation technique.

12. The method of claim 8, wherein the forming of the first gate trench comprises sequentially forming a first upper gate trench and a first lower gate trench in the preliminary impurity region, and forming a preliminary high-concentration impurity region in the preliminary impurity region adjacent to a sidewall of the first upper gate trench before forming the first lower gate trench.

13. The method of claim 8, wherein the low-concentration impurity region is formed while forming the high-concentration impurity region or the second gate trench.

14. The method of claim 8, wherein the high-concentration and low-concentration impurity regions have bottoms positioned at higher levels than a bottom region of the second gate trench.

15. The method of claim 8, wherein forming of the first gate trench comprises:
forming a mask pattern for exposing a predetermined region of the preliminary impurity region;
forming a sacrificial spacer on a sidewall of the mask pattern; and
etching the preliminary impurity region exposed by the sacrificial spacer using the mask pattern and the sacrificial spacer as etching masks.

16. The method of claim 15, further comprising implanting impurity ions into the exposed preliminary impurity region such that the preliminary impurity region exposed by the mask pattern has an impurity concentration gradually reduced downward from a surface of the semiconductor substrate before forming the sacrificial spacer.

17. The method of claim 8, wherein the second gate trench is formed to have a greater width than the first gate trench and to have a spherical shape.

18. The method of claim 8, further comprising forming a gate electrode in the first and second gate trenches, wherein the gate electrode is buried in the first gate trench.

19. The method of claim 8, further comprising a contact plug positioned on the high-concentration and low-concentration impurity regions, wherein the contact plug is a doped poly-silicon layer.

20. A method of fabricating a semiconductor device, comprising:
forming a first gate trench in an active region of a semiconductor substrate;
forming a high-concentration impurity region in the active region adjacent to a sidewall of the first gate trench, the high-concentration impurity region being formed along the sidewall of the first gate trench;
forming a second gate trench beneath the first gate trench;
forming a gate electrode in the first and second gate trenches; and
implanting impurity ions into the active region using the gate electrode as an ion implantation mask, thereby forming a low-concentration impurity region adjacent to the high-concentration impurity region.
